(19) United States
(12) Patent Application Publication
(10) Pub. No.: US 2020/0255733 A1
(43) Pub. Date: Aug. 13, 2020

(54) Fused Encapsulation of Quantum Dots

(71) Applicant: OSRAM Opto Semiconductors GmbH, Regensburg (DE)

(72) Inventors: Weiwen Zhao, Sparks Glenceo, MD (US); Juanita N. Kurtin, Hillsboro, OR (US); Joseph A. Treadway, Portland, OR (US); Brian Theobald, Gladstone, OR (US)

(21) Appl. No.: 16/270,528

(22) Filed: Feb. 7, 2019

(51) Int. Cl. C09K 11/88; H01L 33/50; C09K 11/02

(52) U.S. Cl. CPC C09K 11/883; H01L 2933/0041; C09K 11/025; H01L 33/50

(57) ABSTRACT

A method for fabricating a connected network of oxide-coated semiconductor structure, comprising: preparing a first solution comprising a nanocrystalline material and a first solvent; preparing a second solution comprising a surfactant and a second solvent; adding the first solution and a bifunctional linker to the second solution, thereby preparing a third solution; adding a catalyst, water and a silicate to the third solution; thereby preparing a connected network of oxide-coated semiconductor structure; wherein the ratio of the water to surfactant is more than 3.5. Furthermore, an oxide-coated semiconductor structure and a light source comprising an oxide-coated semiconductor structure are described herein.

### TECHNICAL FIELD

This invention relates to a method for fabricating a connected network of oxide-coated semiconductor structure, a connected network of oxide-coated semiconductor structure prepared by a method of the present invention and a light source comprising a connected network of oxide-coated semiconductor structure of the present invention.

### BACKGROUND

Quantum dots are materials which are beneficial in many applications, but which often cannot withstand thousands of hours of operation under the environmental and operating conditions of many products, for example, light emitting diode (LED) or solar devices.

Networks of semiconductor structures with fused insulator coatings are described, e.g., in U.S. Pat. No. 9,722,147.

Methods of making individually oxide-coated quantum dots are described, e.g., in U.S. Pat. Nos. 9,478,717 and 9,249,354.

### SUMMARY

It is an object of the present invention to obviate the disadvantages of the prior art.

It is a further object of the present invention to provide a method for fabricating a connected network of oxide-coated semiconductor structure.

It is also an object of the present invention to provide a connected network of oxide-coated semiconductor structure prepared by a method of the present invention.

It is a further object of the present invention to provide a light source comprising a connected network of oxide-coated semiconductor structure of the present invention.

In accordance with one object of the present invention a method for fabricating a connected network of oxide-coated semiconductor structure is provided. The method comprises preparing a first solution comprising a nanocrystalline material and a first solvent, preparing a second solution comprising a surfactant and a second solvent, adding the first solution and a bifunctional linker to the second solution, thereby preparing a third solution, and adding a catalyst, water and a metal alkoxide to the third solution, thereby preparing a connected network of oxide-coated semiconductor structure, wherein the ratio of the water to surfactant is more than 3.5.

In accordance with one object of the present invention, a connected network of oxide-coated semiconductor structure is provided. The network of oxide-coated semiconductor structure is prepared by a method according to the present invention.

In accordance with one object of the present invention, a light source is provided. The light source comprises a light emitting diode (LED) and a connected network of oxide-coated semiconductor structure according to the present invention.

### BRIEF DESCRIPTION OF THE DRAWINGS

FIG. 1 shows a transmission electron micrograph illustrating the fused silica morphology;

FIG. 2 shows a luminescence quantum yield as a function of temperature;

FIG. 3 shows a graph showing an accelerated ageing challenge;

FIG. 4 shows a transmission electron micrograph illustrating the fused silica morphology; and

FIG. 5 shows a flow chart of a method for fabricating a connected network of oxide-coated semiconductor structure.

### DETAILED DESCRIPTION OF ILLUSTRATIVE EMBODIMENTS

For a better understanding of the present invention, together with other and further objects, advantages and capabilities thereof, reference is made to the following disclosure and appended claims taken in conjunction with the above-described drawings.

References to the color of the phosphor, LED, or conversion material refer generally to its emission color unless otherwise specified. Thus, a blue LED emits a blue light, a yellow phosphor emits a yellow light and so on.

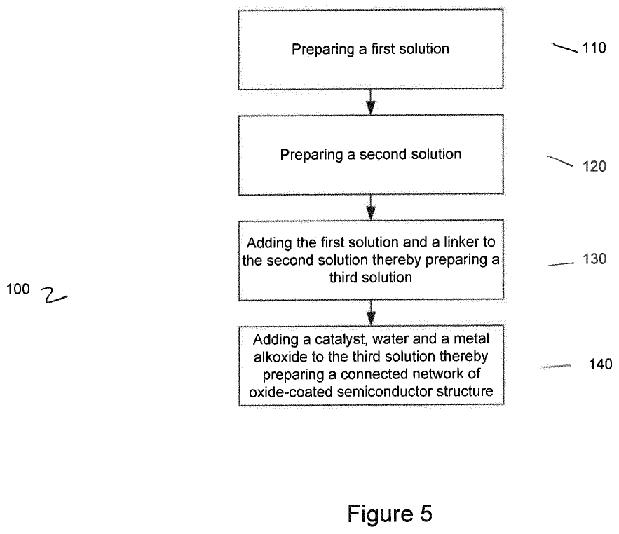

The present invention is directed to a method 100 for fabricating a connected network of oxide-coated semiconductor structure as shown in FIG. 5. The method 100 includes preparing a first solution 110 comprising a nanocrystalline material and a first solvent, preparing a second solution 120 comprising a surfactant and a second solvent, adding the first solution and a bifunctional linker to the second solution 130, thereby preparing a third solution, and adding a catalyst, water and a metal alkoxide to the third solution 140, thereby preparing a connected network of oxide-coated semiconductor structure, wherein the ratio of the water to surfactant is more than 3.5.

According to the present invention, the method comprises the step of preparing a first solution comprising a nanocrystalline material and a first solvent.

In an embodiment of the present invention, the nanocrystalline material comprises a first nanocrystalline material and a second nanocrystalline material.

In an embodiment, the nanocrystalline material forms a quantum dot.

Quantum dots are materials which are beneficial in many applications, but which often cannot withstand thousands of hours of operation under the environmental and operating conditions of many products, for example, light emitting diode (LED) or solar devices. A quantum dot might comprise a core-shell structure. This means that a specific material forms a so-called core, which is at least partially surrounded by at least one shell material. There are also kinds of quantum dots that do not comprise a shell, but only comprise a core material.

In the present application, the first nanocrystalline material might form the nanocrystalline core of a quantum dot and the second nanocrystalline material might form the nanocrystalline shell of the quantum dot.

For example, in an embodiment, the nanocrystalline core is anisotropic. In another example, in an embodiment, the nanocrystalline core is anisotropic and is asymmetrically oriented within the nanocrystalline shell. In an embodiment, the nanocrystalline core and the nanocrystalline shell form a quantum dot. In another embodiment, one or more additional semiconductor layers may surround the quantum dot.

With reference again to the above described nanocrystalline core and nanocrystalline shell, in an embodiment, the nanocrystalline core has a diameter approximately in the range of 2 nm to 6 nm. The nanocrystalline shell has a long axis and a short axis, the long axis having a length approximately in the range of 6 nm to nm to 10 nm greater than the diameter of the nanocrystalline core.

In a particular embodiment, the first nanocrystalline material includes a Group II-VI nanocrystalline material, which might form a nanocrystalline core. The second nanocrystalline material also includes a Group II-VI nanocrystalline material, which might form a nanocrystalline shell, different from the Group II-VI nanocrystalline first material. In the semiconductor structure, the Group II-VI nanocrystalline second material is bonded to and completely surrounds the Group II-VI nanocrystalline first material. In one such embodiment, the Group II-VI nanocrystalline first material is CdSe, and the Group II-VI nanocrystalline second material is CdS. There can optionally be additional Group II-VI shells.

One or more embodiments described herein is directed to a hetero-structure first nanocrystalline material/second nanocrystalline material pairing that is cadmium-free. For example, with reference to the above described nanocrystalline first and second material pairings, in an embodiment, the first nanocrystalline material is a group I-III-VI semiconductor material. In one such embodiment, the second nanocrystalline material is a second group I-III-VI material. For example, a suitable I-III-VI/I-III-VI pairing can include, but is not limited to, copper indium sulfide (CuInS)/silver gallium sulfide (AgGaS₂), copper indium selenide (CuInSe)/AgGaS₂, copper gallium selenide (CuGaSe₂)/copper gallium sulfide (CuGaS₂), or CuGaSe₂/AgGaS₂. In another such embodiment, the second nanocrystalline material is a group II-VI material. For example, a suitable I-III-VI/II-VI pairing can include, but is not limited to, copper indium sulfide (CuInS)/zinc selenide (ZnSe), CuInS/zinc sulfide (ZnS), copper indium selenide (CuInSe)/ZnSe, CuInSe/ZnS, copper gallium selenide (CuGaSe₂)/ZnSe, CuGaSe₂/ZnS, silver gallium sulfide (AgGaS₂)/ZnS, AgGaS₂/ZnSe, or silver gallium selenide (AgGaSe₂)/ZnS, AgGaSe₂/ZnSe.

In a further embodiment, the nanocrystalline materials may be selected from the Group II-VI compounds, Group III-V compounds, Group IV-IV compounds, Group I-III-VI compounds, or any alloy thereof. More specifically the nanocrystalline materials may be chosen from ZnO, ZnS, ZnSe, ZnTe, CdO, CdS, CdSe, CdTe, HgS, HgSe, HgTe, HgO, AlN, AlP, AlAs, AlSb, GaN, GaP, GaAs, GaSb, GaSe, InN, InP, InAs, InSb, TlN, TIP, TlAs, TlSb, PbS, PbSe, PbTe, MgO, MgS, MgSe, alloys thereof, and mixtures thereof.

The nanocrystalline material might be present in a nanocrystalline form having a nanocrystal size of between about 1 nm to about 100 nm. In an embodiment, the nanocrystal size is of between about 1 nm to about 50 nm, preferably of between about 5 nm to about 30 nm.

The nanocrystalline material might be added in an amount of between about 0.1 wt. % to about 3 wt. %, preferably in an amount of between about 0.75 wt. % to about 2 wt. %, more preferred in an amount of between about 1 wt. % to about 1.5 wt. %, with respect to the total amount of the third solution.

The first solution further comprises a first solvent. The solvent might be a pure solvent, or might be a mixture of solvents.

In an embodiment, the first solvent is a non-polar solvent. Examples of non-polar solvents are cyclohexane, carbon tetrachloride, hexane, alkanes, toluene, benzene, and xylene. A preferred first solvent of the present invention is cyclohexane.

The first solution might be prepared by mixing the first nanocrystalline material with the first solvent.

In a further step, a second solution is prepared comprising a surfactant and a second solvent.

The surfactant might be chosen from cationic surfactants such as CTAB (cetyltrimethylammonium bromide), anionic surfactants, non-ionic surfactants, or pluronic surfactants such as Pluronic F 127 (an ethylene oxide/propylene oxide block co-polymer) as well as mixtures of surfactants.

In a preferred embodiment, the surfactant is selected from the group consisting of polyoxyethylene nonylphenylethers.

The surfactant might be added in an amount of about 15 wt. % to about 40 wt. %, preferably in an amount of between about 20 wt. % to about 30 wt. %, more preferred in an amount of between about 20 wt. % to about 25 wt. %, with respect to the total amount of the third solution.

The second solvent might be a pure solvent, or a mixture of solvents.

In an embodiment, the second solvent is a non-polar solvent. Examples of non-polar solvents are cyclohexane, carbon tetrachloride, hexane, alkanes, toluene, benzene, and xylene. A preferred first solvent of the present invention is cyclohexane.

In a preferred embodiment of the present invention, the first solvent and the second solvent are non-polar solvents.

In a further preferred embodiment, the first solvent and the second solvent are the same solvents.

The second solution might be prepared by mixing the surfactant with the second solvent.

In a further step of the method of the present invention, the first solution and a bifunctional linker are added to the second solution, thereby preparing a third solution.

In a preferred embodiment, the bifunctional linker is a silane.

The bifunctional linker might be added as a pure compound or might be added as a mixture of compounds.

Typical examples of silanes are 3-aminopropyltrimethoxysilane (APTMS), 3-mercapto-trimethoxysilane, or a silane comprising a phosphonic acid or carboxylic acid functional group.

The bifunctional linker might be added in an amount of about 0.1 wt. % to about 0.45 wt. %, preferably in an amount of between about 0.2 wt. % to about 0.35 wt. %, with respect to the total amount of the third solution.

In a further step of the method of the present invention, a catalyst, water and a metal alkoxide are added to the third solution.

In an embodiment, the catalyst is a base or an acid. In a preferred embodiment, the catalyst is a base. The catalyst might be a mixture of the catalytic material and water. In this aspect of the embodiment, it is not necessary to add a further amount of water. Alternatively, a further amount of water is added.

The catalyst may be an acid. Examples of acids would be oxyacids (e.g., HNO₃, H₂SO₄, H₂SO₃, carbonic acid) and binary acids (e.g., HCl, HI, HBr).

The method also involves adding a catalyst to the third solution to fuse material formed of the surfactant, the bifunctional linker and the metal alkoxide, providing a connected network. Each of the nanocrystalline material, e.g., a quantum dot, is spaced apart from one another by the connected network. The catalyst may be comprised of, but not limited to, NH₄OH, LiOH, RbOH, CsOH, MgOH, (Me)₄NOH, (Et)₄NOH, or (Bu)₄NOH. Adding the catalyst to the third solution might, e.g., involve adding one mole of the catalyst for every two moles of the material formed of the surfactant, the bifunctional linker and the metal alkoxide. The method also involves adding a metal alkoxide to the third solution.

A metal alkoxide is characterized by the general formula M(OR)ₓ where M is metal, O is oxygen, R is an alkyl group, and x is the number of alkyl groups. In a preferred embodiment, the metal alkoxide is a silicate. In a further preferred embodiment, the bifunctional linker and the metal alkoxide comprise the same metal, e.g., the bifunctional linker is a silane and the metal alkoxide is a silicate.

In an embodiment, the silicate is selected from the group consisting of tetraethylorthosilicate (TEOS), tetramethylorthosilicate.

In an embodiment, the metal alkoxide is selected from the group consisting of titanium isopropoxide, titanium ethoxide, zirconium ethoxide, and aluminum sec-propoxide.

The silicate is preferably added in an amount of about 1 wt. % to about 30 wt. %, preferably in an amount of between about 5 wt. % to about 15 wt. %, more preferred in an amount of between about 8 wt. % to about 10 wt. %, with respect to the total amount of the third solution.

According to the method of the present invention, the ratio of the water to the surfactant is more than 3.5. In a preferred embodiment, the ratio of the water to the surfactant is more than 5. Preferably, the ratio of the water to the surfactant is more than 10 or more than 15. In a preferred embodiment, the ratio of the water to the surfactant is between more than 3.5 to less than 20.

The specific ratio of the water to the surfactant allows the formation of a connected network of oxide coated nanocrystalline material without any further addition of bases, acids, etc. The use of a specific ratio reduces the number of process steps, as the network is formed while preparing an oxide coating on the nanocrystalline material.

In an embodiment, the method of the present invention further comprises the step of isolating the semiconductor structure resulting from the reaction described above, redispersing in a first solvent, adding a further portion of the second solution comprising the surfactant and the second solvent, adding a further portion of the first solution and the bifunctional linker to the second solution, thereby preparing a fourth solution, and adding a further portion of the catalyst, water and the metal alkoxide to the fourth solution; wherein the ratio of the water to surfactant is more than 3.5. In this embodiment, a further coating is preferably added to the connected network of oxide-coated semiconductor structures. The further step might be repeated several times, e.g., two times, three times, four times, or even more times. In this embodiment, further coatings might be added without any intermediate method steps, purification steps, etc.

The first solution, the second solution, the surfactant, the second solvent, the bifunctional linker, the catalyst and the metal alkoxide, as well as the ratio of the water to surfactant correspond to the compounds and ratios as mentioned herein.

According to embodiments of the invention, nanocrystalline material is made robust for certain applications by individually coating the surfaces of the nanocrystalline material with coatings of metal oxide (for example, silica, titania, alumina, etc.). However, the single coating may not be sufficient to protect the nanocrystalline material in all operating or environmental conditions, due to the imperfect or porous coverage of the metal oxide. Adding additional coatings of metal oxide or other insulating material makes the nanocrystalline material more robust by further protecting the surfaces and filling in any imperfections or pores.

The coating might be a so-called insulator layer and covers at least part of the nanocrystalline material, preferably the coating completely covers the nanocrystalline material.

In embodiments, where the nanocrystalline material forms a quantum dot, the coating covers at least part of the quantum dot.

With reference to the above described nanocrystalline core and nanocrystalline shell pairings, in an embodiment, the coating is bonded directly to the nanocrystalline shell. In one such embodiment, the coating passivates an outermost surface of the nanocrystalline shell. In another embodiment, the coating provides a barrier for the nanocrystalline shell and nanocrystalline core impermeable to an environment outside of the coating.

In any case, the coating may encapsulate only a single nanocrystalline shell/nanocrystalline core pairing. The semiconductor structure might further include a nanocrystalline outer shell at least partially surrounding the nanocrystalline shell, between the nanocrystalline shell and the coating. The nanocrystalline outer shell is composed of a third nanocrystalline material different from the nanocrystalline material of the shell and, possibly, different from the nanocrystalline material of the core.

With reference again to the above described nanocrystalline core and nanocrystalline shell pairings, in an embodiment, the coating is composed of a layer of material such as a metal oxide. In an embodiment, the coating is an amorphous layer. In an embodiment, the coating is composed of, but not limited to, silica (SiOₓ), titanium oxide (TiOₓ), zirconium oxide (ZrOₓ), alumina (AlOₓ), or hafnia (HfOₓ). In one such embodiment, the coating is silica having a thickness approximately in the range of 3 nm to 500 nm.

With reference again to the above described oxide-coated nanocrystalline core and nanocrystalline shell pairings, in an embodiment, an outer surface of the coating is ligand-free. However, in an alternative embodiment, an outer surface of the coating is ligand-functionalized. In one such embodiment, the outer surface of the coating is ligand-functionalized with a ligand such as, but not limited to, a bifunctional linker having one or more hydrolyzable groups or a functional or non-functional bipodal silane. In another such embodiment, the outer surface of the coating is ligand functionalized with a ligand such as, but not limited to, mono-, di-, or tri-alkoxysilanes with three, two or one inert or organofunctional substituents of the general formula (R¹O)₃SiR²; (R¹O)₂SiR²R³; (R¹O)SiR²R³R⁴, where R¹ is methyl, ethyl, propyl, isopropyl, or butyl, R², R³ and R⁴ are identical or different and are H substituents, alkyls, alkenes, alkynes, aryls, halogeno-derivates, alcohols, (mono, di, tri, poly) ethyleneglycols, (secondary, tertiary, quaternary) amines, diamines, polyamines, azides, isocyanates, acrylates, metacrylates, epoxides, ethers, aldehydes, carboxylates, esters, anhydrides, phosphates, phosphines, mercaptos, thiols, sulfonates, and are linear or cyclic, a silane with the general structure (R¹O)₃Si—(CH₂)ₙ—R—(CH₂)ₙ—Si(RO)₃ where R and R¹ is H or an organic substituent selected from the group consisting of alkyls, alkenes, alkynes, aryls, halogeno-derivates, alcohols, (mono, di, tri, poly) ethyleneglycols, (secondary, tertiary, quaternary) amines, diamines, polyamines, azides, isocyanates, acrylates, metacrylates, epoxies, ethers, aldehydes, carboxylates, esters, anhydrides, phosphates, phosphines, mercaptos, thiols, sulfonates, and are linear or cyclic, a chlorosilane, or an azasilane.

In another such embodiment, the outer surface of the coating is ligand-functionalized with a ligand such as, but not limited to, organic or inorganic compounds with functionality for bonding to a silica surface by chemical or non-chemical interactions such as but not limited to covalent, ionic, H-bonding, or Van der Waals forces. In yet another such embodiment, the outer surface of the coating is ligand-functionalized with a ligand such as, but not limited to, the methoxy and ethoxy silanes (MeO)₃SiAllyl, (MeO)₃SiVinyl, (MeO)₂SiMeVinyl, (EtO)₃SiVinyl, EtOSi(Vinyl)₃, mono-methoxy silanes, chloro-silanes, or 1,2-bis-(triethoxysilyl)ethane.

In any case, in an embodiment, the outer surface of the coating is ligand-functionalized to impart solubility, dispersability, heat stability, photo-stability, or a combination thereof, to the semiconductor structure. For example, in one embodiment, the outer surface of the coating includes OH groups suitable for reaction with an intermediate linker to link small molecules, oligomers, polymers or macromolecules to the outer surface of the coating, the intermediate linker one such as, but not limited to, an epoxide, a carbonyldiimidazole, a cyanuric chloride, or an isocyanate.

With reference again to the above described nanocrystalline core and nanocrystalline shell pairings, in an embodiment, the nanocrystalline core has a diameter approximately in the range of 2 nm to 6 nm. The nanocrystalline shell has a long axis and a short axis, the long axis having a length approximately in the range of 6 nm to 40 nm, and the short axis having a length approximately in the range of 1 nm to 10 nm greater than the diameter of the nanocrystalline core. The coating has a thickness approximately in the range of 1 nm to 50 nm along an axis co-axial with the long axis and has a thickness approximately in the range of 3 nm to 50 nm along an axis co-axial with the short axis. In other embodiments, the thickness of the coating may be greater than 50 nm, for example, up to 500 nm.

Additional aspects of the oxide coating material (e.g., silica) can involve somewhat more sophisticated control of the shelling process, i.e., the layering of the nanocrystalline material. For example, in an embodiment, the thickness of the coating can be controlled approximately in a range of about 0 to about 100 nm total diameter with a delta of approximately 5 nm. In one such embodiment, an amount of the silicate is increased at the beginning of a layering reaction (i.e., the addition of the oxide coating), and further injecting additional metal alkoxide one or more additional times throughout the layering process.

In an embodiment, an approach is increasing the reactivity of the metal alkoxide in a balanced way such that the nanocrystalline material, such as the quantum dot nanoparticles, seed the growth of the coating, but additionally sufficient metal alkoxide is present to allow fusion of growing oxide spheres at the same time.

In one embodiment, the ratio of the metal alkoxide (e.g., TEOS) to seed particles is increased until fused structures result.

In another embodiment, a more reactive version of the metal alkoxide (e.g., tetramethylorthosilicate (TMOS)) is used instead of less reactive versions of the metal alkoxide, e.g., TEOS.

Typically, for example, reducing the surfactant concentration while holding other stoichiometries constant might favor the formation of extended/entangled fused semiconductor structures such as those described herein. It can even be useful to severely restrict the surfactant level up to the onset of reaction solution turbidity. The interplay between surfactant, solvent, and water levels allows for several combinations of reagents that would result in morphological variations in the fused semiconductor structure. For example, increasing the water to solvent ratio at fixed surfactant concentration might be expected to similarly result in a semi-continuous aqueous phase that would favor the fused oxide-coated semiconductor structure.

The oxide coating on the nanocrystalline material, e.g., on a quantum dot, preferably protects the nanocrystalline material from water, vapor, oxygen etc. in order to extend the lifetime of the nanocrystalline material and structures and devices comprising such nanocrystalline material. Examples of devices comprising quantum dots as such nanocrystalline material are quantum dot-based lighting, display devices, as well as other devices that include quantum dots.

The method of the present invention might also be a sol-gel process that encapsulates the nanocrystalline material individually, i.e., that provides a coating on the nanocrystalline material. Therefore, the layer might act as a barrier towards heat, moisture and oxygen.

It is a further object of the present invention to provide a connected network of oxide-coated semiconductor structure prepared by a method according to the present invention.

A connected network of oxide-coated semiconductor structures of the present invention might comprise a nanocrystalline core, a nanocrystalline shell and a coating. The nanocrystalline core and the nanocrystalline shell might form a quantum dot. The nanocrystalline core and the nanocrystalline shell preferably comprise the nanocrystalline material as described herein. The coating preferably comprises the material as described herein.

In an exemplary embodiment, the nanocrystalline core comprises CdSe, the nanocrystalline shell comprises CdS and the coating comprises silica.

In an embodiment, the semiconductor structure further comprises a nano-crystalline outer shell composed of a third semiconductor material different from the nanocrystalline materials of, e.g., the core and the shell. The third semiconductor material at least partially surrounding the nanocrystalline material and, in one embodiment, the nanocrystalline material completely, surrounds the nanocrystalline material. In a particular embodiment, the second (e.g., shell) nanocrystalline material one such as, but not limited to, zinc selenide (ZnSe), silver gallium sulfide (AgGaS₂) or copper gallium sulfide (CuGaS₂), and the third (outer shell) semiconductor material is zinc sulfide (ZnS).

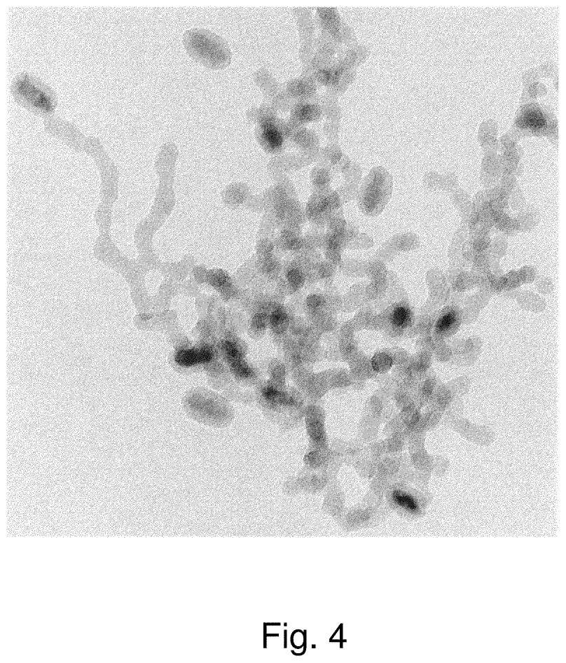

While the shape of the quantum dot depicted in FIG. 4 is a type of a rod, it is to be appreciated that the methods described herein are not limited by the shape of the quantum dot and could be applied to coated quantum dots of many different shapes, including but not limited to spheres, rods, tetrapods, teardrops, sheets, etc. It is not limited by the composition of the quantum dot and can be applied to quantum dots made from a single material or multiple materials in either a core/shell/optional shell/optional shell configuration or an alloyed composition. The semiconductor materials may be selected from the Group II-VI compounds, Group III-V compounds, group IV-IV compounds, Group I-III-VI compounds, or any alloy thereof. More specifically the semiconductor materials may be chosen from ZnO, ZnS, ZnSe, ZnTe, CdO, CdS, CdSe, CdTe, HgS, HgSe, HgTe, HgO, AlN, AlP, AlAs, AlSb, GaN, GaP, GaAs, GaSb, GaSe, InN, InP, InAs, InSb, TlN, TlP, TlAs, TlSb, PbS, PbSe, PbTe, MgO, MgS, MgSe, alloys thereof, and mixtures thereof.

Connected networks of oxide-coated semiconductor structures comprising a nanocrystalline material and an oxide layer might have a high photoluminescence quantum yield (PLQY) and improved moisture resistance.

In an embodiment of the present invention, the nanocrystalline material is a quantum dot and the coating is a layer of oxide optionally comprising other ligands to provide a fused structure. With a method of the present invention, such as a sol-gel process, the quantum dot might be encapsulated individually in a fused oxide shell, resulting in a very stable high PLQY quantum dot particle. The oxide shell might act as an insulating shell. In addition, the layer might improve the wet high temperature operating life (WHTOL) of individually encapsulated quantum dots.

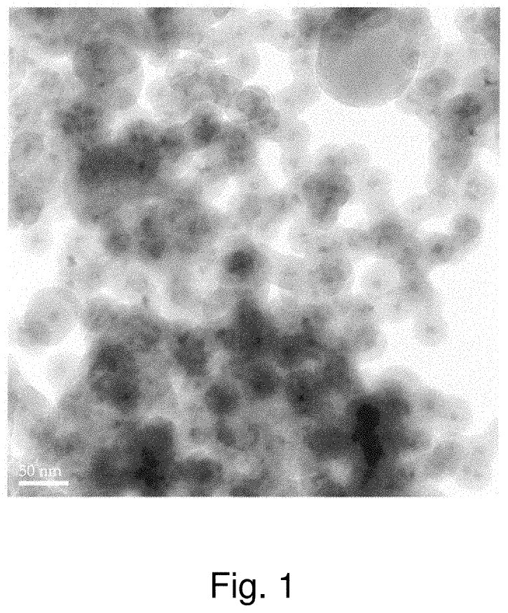

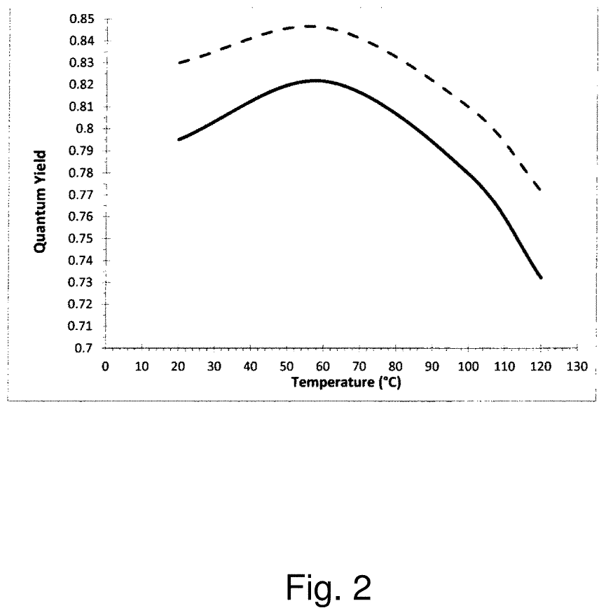

FIG. 2 shows the luminescence quantum yield as a function of temperature. Silica-encapsulated particles such as those shown in FIG. 1 were dispersed in cured crosslinked silicone and irradiated with a flux of approximately 10 W/cm² at approximately 450 nm. The dotted line represents the quantum yield-temperature curve for a connected network of oxide-coated semiconductor structure according to the present invention, whereas the continuous line represents the quantum yield-temperature curve for the same quantum dot using a different method of applying a silica layer. The method for the continuous line is described in U.S. Pat. No. 9,567,514.

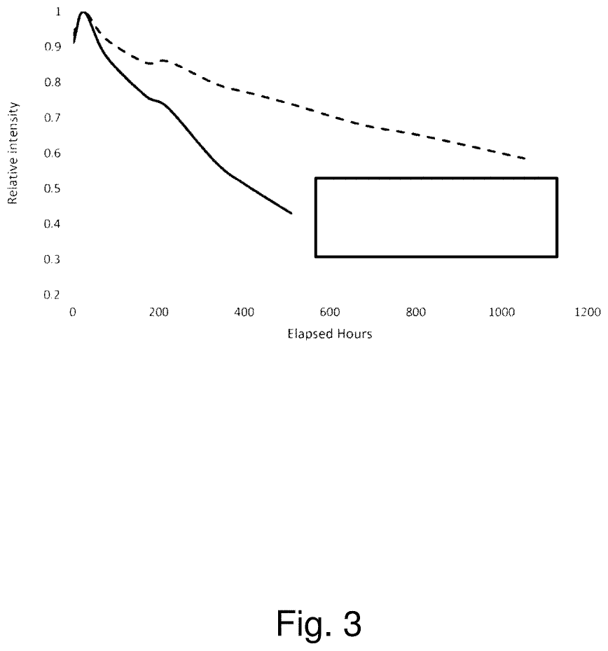

FIG. 3 shows an accelerated ageing challenge. The intensity of red (quantum dot) light output as a function of time in an LED device (blue chip, red quantum dot downconverter, silicone matrix) at 85° C. and 85% relative humidity is presented. The curves are normalized to the maximum intensity. The dotted line represents the curve progression of a semiconductor structure according to the present invention, whereas the continuous line represents the curve progression for the same quantum dot using a different method of applying a silica layer. The method for the continuous line is described in U.S. Pat. No. 9,567,514.

Often, even more favorable performance characteristics are obtained by employing a second, or a second and third (etc.) coating (e.g., silica coating) using the fused semiconductor structure as feedstock in a multi-laminar approach as previously described (e.g., U.S. Pat. No. 9,567,514). Such a multi-laminar approach was utilized in the generation of the data included in FIGS. 2 and 3.

FIG. 4 is an electron micrograph of a fused silica network resulting from the use of TMOS instead of TEOS in a method according to the present invention. While not identical to the image in FIG. 1, a functionally similar motif results.

The key to produce structures as shown in the TEM figures, FIG. 1 and FIG. 4, is to use the correct ratio of nanocrystalline material (e.g., quantum dot), water, surfactant and metal alkoxide (e.g., TEOS) so that each nanocrystalline material (e.g., quantum dot) is individually layered and the semiconductor structures are fused with each other.

It is a further object of the present invention to provide a light source comprising a light emitting diode (LED) and a connected network of oxide-coated semiconductor structure according to the present invention.

A light emitting diode (LED) of a light source of the present invention typically emits blue light or UV light. Preferred LEDs are blue light LEDs.

### Examples

For example, in an embodiment, a coating of silica is formed using a reverse micelle sol-gel reaction. In one such embodiment, using the reverse micelle sol-gel reaction includes dissolving the nanocrystalline shell/nanocrystalline core pairing in a first non-polar solvent to form a first solution. Subsequently, the first solution is added along with a species such as, but not limited to, 3-aminopropyltrimethoxysilane (APTMS), 3-mercapto-trimethoxysilane, or a silane comprising a phosphonic acid or carboxylic acid functional group, to a second solution having a surfactant dissolved in a second non-polar solvent. Subsequently, ammonium hydroxide and tetraorthosilicate (TEOS) are added to the second solution.

While there have been shown and described what are at present considered to be preferred embodiments of the invention, it will be apparent to those skilled in the art that various changes and modifications can be made herein without departing from the scope of the invention as defined by the appended claims. The disclosure rather comprises any new feature as well as any combination of features, which in particular includes any combination of features in the appended claims, even if the feature or combination is not per se explicitly indicated in the claims or the examples.

What is claimed is:

1. A method for fabricating a connected network of an oxide-coated semiconductor structure, the method comprising:
preparing a first solution comprising a nanocrystalline material and a first solvent;
preparing a second solution comprising a surfactant and a second solvent;
adding the first solution and a bifunctional linker to the second solution, thereby preparing a third solution; and
adding a catalyst, water and a metal alkoxide to the third solution, thereby preparing a connected network of the oxide-coated semiconductor structure, wherein a ratio of the water to surfactant is more than 3.5.

2. The method according to claim 1, wherein the first solvent and the second solvent are a non-polar solvent.

3. The method according to claim 1, wherein the catalyst is an acid or a base.

4. The method according to claim 1, wherein the catalyst is a base selected from the group consisting of ammonium hydroxide, alkali hydroxides, alkaline earth hydroxides, alkali alkoxides, carbonate, borate and phosphates.

5. The method according to claim 1, wherein the bifunctional linker is a silane.

6. The method according to claim 5, wherein the silane is a silane comprising a phosphonic acid group or a carboxylic acid group.

7. The method according to claim 5, wherein the silane is selected from the group consisting of 3-aminopropyltrimethoxy-silane (APTMS), 3-mercaptopropyltrimethoxysilane, and longer-chain variants.

8. The method according to claim 1, wherein the surfactant is selected from the group consisting of polyoxyethylene nonphenylether, dioctyl sulfosuccinate, certrimonium bromide, zwitterionic species, polyvinyl alcohols, dodecylsulfonate, polyoxyalkylenes, oleic acid, including block copolymers and mixtures of thereof.

9. The method according to claim 1, wherein the metal alkoxide is a silicate.

10. The method according to claim 9, wherein the silicate is selected from the group consisting of tetraethylorthosilicate, tetramethylorthosilicate, and silicic acid.

11. The method according to claim 1, wherein the metal alkoxide is selected from the group consisting of titanium isopropoxide, titanium ethoxide, zirconium ethoxide, and aluminum sec-propoxide.

12. The method according to claim 1, wherein the ratio of the water to the surfactant is more than 5.

13. The method according to claim 1, wherein the nanocrystalline material comprises a first nanocrystalline material and a second nanocrystalline material.

14. The method according to claim 1, wherein the nanocrystalline material forms a quantum dot.

15. The method according to claim 1, further comprising:
isolating the connected network of the oxide-coated semiconductor structure;
redispersing the connected network of the oxide-coated semiconductor structure in the first solvent;
adding a further portion of the second solution and the bifunctional linker to the second solution, thereby preparing a fourth solution; and
adding a further portion of the catalyst, water and the metal alkoxide to the fourth solution, wherein the ratio of the water to surfactant is more than 3.5.

16. The method according to claim 1, wherein a coating comprises a metal oxide.

17. The method according to claim 1, wherein a coating comprises at least one metal oxide selected from the group consisting of silica (SiOₓ), titanium oxide (TiOₓ), zirconium oxide (ZrOₓ), alumina (AlOₓ), magnesium oxide (MgOₓ), hafnia (HfOₓ), barium oxide (BaO), bismuth oxides (BiOₓ), tin oxides (SnOₓ), and mixed oxides.

18. A connected network of the oxide-coated semiconductor structure prepared by the method according to claim 1.

19. A light source comprising:
a light emitting diode (LED); and
the connected network of the oxide-coated semiconductor structure according to claim 18.
